(19) United States
(12) Patent Application Publication
(10) Pub. No.: US 2005/0102594 A1
(43) Pub. Date: May 12, 2005

(54) Method for test application and test content generation for AC faults in integrated circuits

(75) Inventors: Sujit Dey, San Diego, CA (US); Xiaoliang Bai, La Jolla, CA (US); Li Chen, Hillsboro, OR (US); Angela Krstic, San Diego, CA (US)

Correspondence Address: GREER, BURNS & CRAIN, 300 S WACKER DR, 25TH FLOOR, CHICAGO, IL, 60606, US

(73) Assignee: THE REGENTS OF THE UNIVERSITY OF CALIFORNIA

(21) Appl. No.: 10/951,278

(22) Filed: Sep. 27, 2004

Related U.S. Application Data
(60) Provisional application No. 60/513,434, filed on Oct. 22, 2003.
(60) Provisional application No. 60/506,711, filed on Sep. 26, 2003.

(51) Int. Cl. G06F 11/00; G01R 31/28

(52) U.S. Cl. 714/733

(57) ABSTRACT

A method for generating a software-based self-test in an integrated circuit includes extracting constraints for corresponding instructions for the integrated circuit, modeling the constraints for a plurality of timeframes and performing constrained test pattern generation on the integrated circuit using the models. An automatic test pattern generation method for an AC fault in an integrated circuit includes identifying a current desired condition for triggering the AC fault, determining whether the current desired condition is feasible, and identifying a subsequent desired condition for triggering the AC fault if the current desired condition is not feasible. The method further includes determining whether the subsequent desired condition for triggering the AC fault is feasible, and searches for test vectors for realizing the current desired condition or subsequent desired condition which is determined to be feasible.

### STATEMENT OF GOVERNMENT INTEREST

The invention was made with Government assistance under DARPA Grant No. 98-DT-660. The Government has certain rights in this invention.

### FIELD OF THE INVENTION

A field of the invention is integrated circuits generally. More specifically, the invention relates to software and methods of integrated circuit testing and integrated circuit manufacturing.

### BACKGROUND OF THE INVENTION

Due to the increasing complexity of modern processors and significant process variations in advanced technologies, testing for high-performance chips becomes expensive and time consuming. Signal integrity problems relating to AC faults (also known as timing-related faults) can severely affect the performance of and even cause functional errors in manufactured chips.

Various test methodologies such as scan test, built-in self-test (BIST) and functional test have been adopted to ensure high-quality chips. Scan test can be systematically applied to complex designs. It enables automatic test generation and enhanced diagnostic resolution. BIST generates at-speed tests and helps to reduce test volume. Both scan test and BIST can be used to detect signal integrity problems. However, signal integrity problems are strongly dependent on voltage, temperature and timing properties. Structural tests such as scan and BIST test apply vectors in an “artificial” environment, the voltage, temperature and timing of the module-under-test (MUT) and surrounding logics are different from those in the operational mode, leading to over-test or under-test for the manufactured chips.

Functional tests exercise the MUT at operational speed without introducing area and delay overhead, and are performed in a chip's natural working environment. In spite of these benefits, several challenges frequently hinder the application of functional tests. High-speed testers are prohibitively expensive and the performance gap between automated test equipments (ATE) and device I/O speed is increasing. Tester timing inaccuracies are becoming comparable to the cycle time of the fastest devices on chip. Also, test generations are mostly time consuming and expensive. Many tests are migrated from design verification suite without targeting any physical defects, and need to be augmented with manually developed tests. Further, testing for signal integrity problem needs layout information that is available in late design cycle, resulting in a pressing test generation time.

Software-based self-test (SBST) has been proposed to alleviate the need for high-speed testers. SBST uses on-chip programmable resources such as processors to generate tests and compress test results, utilizing low-speed testers. To ease the burden of functional test generation, methods of using random instruction sequences have been developed. Since such a test generation process is not defect-oriented, to achieve high defect coverage it requires a long test program with increased testing cost and fault simulation time. Deterministic test methods have been developed to mitigate this problem. Based on a divide-and-conquer approach, SBST first generates tests for a specific MUT. Processor instructions are then used as a vehicle for delivering the test patterns to MUTs and collecting test responses.

Unlike scan test that possesses enhanced controllability and observability on internal modules, for SBST, many module-level automatic test program generation (ATPG) vectors cannot be delivered to the MUT. The instruction set architecture (ISA) and surrounding logic impose various requirements on the input vectors and the output observable nodes. These special requirements determine what kind of vectors can be applied by processor instructions, and are called instruction-imposed constraints. To guarantee the delivery of module-level ATPG vectors by instructions, these constraints should be considered during test generation.

Automated methods for extracting surrounding-logic-imposed constraints have been proposed. Since they are only a subset of instruction-imposed constraints, these constraints cannot be directly applied to SBST. Symbolic simulation was used to extract constraints imposed by ISA. Using these constraints and targeting path delay faults, an automated test program synthesis method was developed based on a backtrack-based searching algorithm. However, scalability remains a big challenge as symbolic simulation in its present form is not feasible for large integrated circuits. In “A Scalable Software-Based Self-Test Methodology for Programmable Processors,” Proc. Design Automation Conference, June 2003, pp. 548-553 by L. Chen, S. Ravi, A. Raghunathan and S. Dey (Chen et al.), which is incorporated herein by reference, a systematic SBST methodology was proposed using a simulation-based constraint extraction method and a constrained ATPG method, enabling automatic test program generation for stuck-at faults in industrial-size processors. As known in the art, logical faults represent the effect of physical faults on the behavior of the modeled system. A short between ground or power and a signal line can make the signal remain at a fixed voltage level. The corresponding logical fault consists of the signal being “stuck at” a fixed logic value v (where v is 0 or 1), and it is denoted by s-a-v.

While a stuck-at fault can be detected by applying a single test vector at any speed, an AC fault such as a crosstalk-induced fault can only be detected by applying a sequence of vectors at the operational speed. The requirements of generating consecutive multiple vectors and considering instruction-imposed constraints pose difficult challenges on test program generation.

As a major source of signal integrity problem, crosstalk noise, for example, can cause functional and timing errors. A wire, whose signal is under concern, is a victim. An aggressor is a net whose signal transitions can potentially deteriorate the victim's signal because of a large coupling capacitance or a weak and sensitive victim wire. Various crosstalk noise effects can cause failures in the circuit-under-test (CUT). Due to random defects and excessive process variations, a large noise can cause logic and timing failures. Crosstalk-induced logic and transition faults may include positive glitch, negative glitch, rising delay, falling delay, rising speedup and falling speedup, as shown in FIGS. 1A-1F, respectively.

To test a given crosstalk fault using SBST, a test program launches test vectors to trigger a set of aggressors, sensitizes a propagation path and stores the test results to the memory. It is a multiple-timeframe test generation problem. Like testing for stuck-at faults in SBST, vectors that can be delivered by instructions are limited. In order to be able to translate ATPG results into legal instructions, module-level ATPG should be guided by instruction-imposed constraints.

In an SBST technique that enable automatic test program generation for stuck-at faults, test vectors are delivered to the MUT in functional mode by instructions. Vectors that can be delivered by each instruction form a subset of the original input space. Since not all vectors can be generated in functional mode, the superset of all the instruction-related subsets composes a constrained input space A. Correspondingly, this reduced input space maps to a subset of the fault universe B, as shown in FIG. 2. Faults belonging to this fault subset are those detectable by functional vectors. For a functionally detectable fault (such as fault f), an ATPG tool should be guided to find a “legal” functional vector (t₂) that can be delivered by instructions (i₁, i₂), instead of an “illegal” vector (t₁).

In Chen et al. described above, an enumeration-based methodology was developed that enables automatic test program generation for stuck-at faults. Constraints were first extracted for each instruction. In “A Novel Functional Test Generation Method for Processors using Commercial ATPG,” Proc. Intl. Test Conference, November 1997, pp. 743-752, by R. Tupuri and J. Abraham (Tupuri et al.), which is incorporated herein by reference, a concept of virtual constraint circuit (VCC) was introduced that was later extended and adapted for SBST in Chen et al. The VCCs enforce instruction-imposed constraints on the MUT, providing constraint information in the form of logic circuits. Controllability VCCs (CVCCs) and observability VCCs (OVCCs) are attached to the inputs and outputs of the MUT, respectively. Controllability is the ability to establish a specific value at each node in a circuit by setting values on the circuit's inputs. Observability is the ability to determine the signal value at any node in a circuit by controlling the circuit's inputs and observing its outputs. Constrained test generation is performed on a CUT containing the MUT and the VCCs. The primary inputs (PI) of controllability VCCs are mapped to settable fields (e.g. operands, source and destination registers) that are controllable in instructions. The primary outputs (PO) of observability VCCs are fields that can be mapped and stored to the memory. Test generation is performed by automatically enumerating constraints for each instruction in the ISA. This methodology provides an efficient, scalable test program generation solution for stuck-at faults.

However, in testing for AC faults such as a crosstalk fault, this method meets severe challenges. To detect a crosstalk fault, a sequence of test vectors needs to be delivered by multiple instructions. FIG. 3 shows a test program that uses two instructions (instructions A and B) to deliver test vectors to a MUT in two different timeframes. Other peripheral instructions (instructions 1-5 and 8) are used to setup appropriate operands for these two test-delivery instructions. Since instructions from different timeframes impose different constraints, the MUT will be augmented with different input/output VCCs in different timeframes. An ATPG tool has to handle a problem that keeps changing across timeframes.

In addition, the instruction sequence in a test program template predefines the best vectors that can be delivered to detect AC failures. An example is shown in FIGS. 4A-4B. For the same victim wire in the same MUT, test generations were performed with different constraints from template T₁ (FIG. 4A) and T₂ (FIG. 4B), respectively. Here T₂ has the potential to trigger a larger noise than T₁. In the test generation process for stuck-at faults, a fault can be removed from fault list if a test vector is successfully generated under any template. On the contrary, for crosstalk fault we have to enumerate all the possible instruction sequences for every fault, keeping records of test results and compare these results to find the instruction sequence causing the largest noise. Given a large number of instructions, the enumeration-based method becomes extremely expensive.

Various automatic test pattern generation (ATPG) methods that may be employed in software-based self-test (SBST) methods and other tests such as scan and BIST are known in the art. Structural-based ATPG methods for crosstalk noise induced by a single aggressor is one example. Recently, timed test pattern generation method for switch failures in domino CMOS has been proposed. Also, a dynamic timing analysis has been used to generate test patterns for delay faults in static CMOS circuit. Even though these methods can consider multiple aggressors, the computationally expensive circuit-level timing simulations hurt the scalability of the proposed methods.

Boolean satisfiability (SAT) based ATPG methods for stuck-at faults exhibit advantages such as uniformity and flexibility. A SAT-based crosstalk noise analysis method was proposed that considers both temporal and functional information. However, the high complexity of general purpose SAT-solver makes this method impractical.

FIG. 15 shows a circuit under test (CUT) and the logic constraints of its signal variables in conjunctive normal form (CNF). Each basic logic gate has its corresponding CNF formula. For the AND gate in FIG. 15, with inputs a, b and output c, the logic relation is c=a b, and the equivalent CNF formula is:
(a+\overline{c})(b+\overline{c})(\overline{a}+\overline{b}+c)

This formula will evaluate to “1” if and only if the values of a, b and c are consistent with the truth table of the AND gate. For each gate in the circuit, the CNF formulae must be independently satisfied, and the conjunction of the CNF formulae of all the gates must also be satisfied. The CNF formula provides a search space for test vectors.

During ATPG, in order to determine whether the error has been activated and propagated to POs, part of the circuit needs to be duplicated. For example, if for the circuit shown in FIG. 15, the fault under concern is net c stuck-at 1 (s-a-1), then a variable c′ is added to represent the faulty circuit. The OR gate is duplicated, and another PO e′ is added to represent the PO in the faulty circuit. The modified circuit and its augmented CNF formula are shown in FIG. 16. Compared to structural-based ATPG algorithms, the lack of structural information in the early SAT-based ATPG algorithms and the inability to use many heuristics used by structural-based algorithms resulted in a relatively slow performance. To overcome this drawback, various methods have been developed, including building structural information together with an implication graph.

An implication graph (IG) is a directed graph. The nodes represent logic variables and the edges represent logic implications. In building the implication graph, binary CNF clauses are generated and directly transformed into implications. For example, the binary clause (a+c) of an AND gate, is logically equivalent to (c→a)·(\overline{a}→\overline{c}). Ternary clauses can also be transformed. For example, the ternary clause (\overline{a}+\overline{b}+c) of an AND gate is transformed into an equivalent logic relation: ((a·b)→c)·((a·\overline{c})→\overline{b})·((b·\overline{c})→a).

Based on these transformations, an implication graph can be constructed. The implication graph contains two kinds of nodes: variable nodes and logic “Λ” (AND) nodes. For example, FIG. 17 shows the implication graph for a two-input AND gate, with inputs a and b and output c. In an IG, according to the physical relation between logic variables, the edges that denote implications are labeled as f (forward), b (backward) and o (other). Because the structural information is embedded in the implication graph, heuristics from structural algorithms can be adopted. Another advantage of implication graph is that algorithms only need to handle two kinds of nodes: the signal nodes and the logic “Λ” nodes. Compared to structural-based methods, which need to check a look-up table for different logic gates and logic operations, the IG enables faster logic implication and justification. The method employing the implication graph shows significant improvement over previous ATPG algorithms. However, this method still needs to duplicate the whole implication graph. This imposes a large memory requirement.

### SUMMARY OF THE INVENTION

The present invention is directed to a method for generating a test program for a software-based self-test in an integrated circuit. The method includes extracting constraints for corresponding instructions for the integrated circuit, modeling the constraints for a plurality of timeframes and performing constrained test pattern generation on the integrated circuit using the models. The result from the test pattern generation is then converted to at least one instruction executable by the integrated circuit.

The present invention is also directed to an automatic test pattern generation method for an AC fault in an integrated circuit. The method includes identifying a current desired condition for triggering the AC fault, determining whether the current desired condition for triggering the AC fault is feasible, and identifying a subsequent desired condition for triggering the AC fault if the current desired condition is not feasible. The method then determines whether the subsequent desired condition for triggering the AC fault is feasible, and searches for test vectors for realizing the current desired condition or subsequent desired condition which is determined to be feasible for triggering the AC fault.

### BRIEF DESCRIPTION OF THE DRAWINGS

FIGS. 1A-1F illustrate different types of crosstalk faults;

FIG. 2 is a diagram for illustrating requirements for detecting a functionally detectable fault;

FIG. 3 is a diagram for illustrating a test program for delivering test vectors to a module-under-test (MUT);

FIGS. 4A and 4B are diagrams illustrating the different results obtained using different constraints;

FIG. 5 is a block diagram embodying a software-based self-test in accordance with one embodiment of the present invention;

FIG. 6 is a flowchart illustrating the three stages involved in generating a test program in accordance with an embodiment of the present invention;

FIG. 7 is a flowchart illustrating the steps included in the first stage shown in FIG. 6;

FIG. 8 is a flowchart illustrating the steps included in the second stage shown in FIG. 6;

FIG. 9 is a sample diagram illustrating a super virtual constraint circuit in accordance with one embodiment of the present invention;

FIG. 10 is a diagram illustrating a manner in which the complexity of a a super virtual constraint circuit is reduced;

FIG. 11 is a flowchart illustrating the steps included in the third stage shown in FIG. 6;

FIGS. 12A-12C are sample test results and instructions generated as a result of performing a constrained ATPG operation;

FIGS. 13A and 13B are samples explaining situations in which a potential data conflict may arise in generating the test program;

FIG. 14 is a sample test program generated in accordance with the one embodiment of the present invention;

FIG. 15 is a sample circuit under test (CUT) and the logic constraints of its signal variables in conjunctive normal form (CNF);

FIG. 16 is the circuit shown in FIG. 15 modified to add a faulty circuit;

FIG. 17 is an implication graph for a two-input AND gate;

FIGS. 18A and 18B is a circuit of an AND gate with a D frontier added prior to and after propagation through the AND gate, respectively;

FIGS. 19A-19B illustrate the operation of the circuit of FIGS. 18A and 18B in an implication graph;

FIG. 20 is a sample circuit having multiple aggressors and one victim;

FIG. 21 is a BDD tree for determining feasible aggressors;

FIG. 22 is the BDD tree of FIG. 21, simplified using a search algorithm in accordance with one embodiment of the present invention;

FIG. 23 is a implication graph for a NAND gate and an OR gate used for modifying the BDD tree of FIG. 22; and

FIG. 24 is a flowchart describing steps involved in one embodiment of the ATPG method of the present invention.

### DETAILED DESCRIPTION OF THE PREFERRED EMBODIMENTS

The present invention is directed to a software-based self-test (SBST) method for testing AC fault models such as crosstalk faults, IR drop induced timing faults and path delay faults, in programmable integrated circuits such as microprocessors, micro-controllers, embedded processors, digital signal processors, etc. Different from testing for stuck-at faults, testing for AC faults (such as crosstalk faults) requires a sequence of test vectors delivered at the operational speed. SBST method applies tests in functional mode using instructions. Different instructions impose different controllability and observability constraints on a module-under-test (MUT). As a result, complexity of searching for an appropriate sequence of instructions and operands becomes prohibitively high. One embodiment of the present invention combines structural test generation technique with instruction-level constraints. A MUT is duplicated in several time frames, and augmented with Super Virtual Constraint Circuits (SuperVCCs), which guide an automatic test pattern generation (ATPG) tool to select appropriate test instructions and operands. The present invention enables automatic test program generation and high-fidelity test solution for AC failures.

The present invention is also directed to an automatic test pattern generation (ATPG) method. Given an AC fault, the ATPG algorithm first identifies a desired condition for triggering the AC fault and checks for potential logic conflicts by using an implication graph (IG). If a logic conflict exists, the present invention will identify a subsequent desired condition for triggering the AC fault. As a result, a potential conflict free (feasible) desired condition will be identified. In the second phase, structural algorithms and Boolean satisfiability algorithms are used to search for vectors than can justify the desired condition.

In one embodiment, present ATPG algorithm generates test patterns for crosstalk induced transition faults. Given a victim and a set of aggressors, the ATPG method first checks for potential logic conflicts by using an implication graph (IG). The conflicts are results of logic relation among the victim, the aggressors, as well as mandatory assignments on the propagation path(s). If a logic conflict(s) exists, the proposed algorithm will automatically search for a subset of compatible aggressors based on weights assigned to aggressors. As a result, a set of potentially feasible aggressors will be proposed as objectives for justification. In the next phase, a modified PODEM algorithm is used to search for vectors that can justify the required logic value for the victim, activate the aggressors and sensitize a propagation path. The present structural Boolean-satisfiabilitity (SAT) based SAT-based ATPG method combines advantages from SAT-based methods and structural-based methods to achieve flexibility and efficiency.

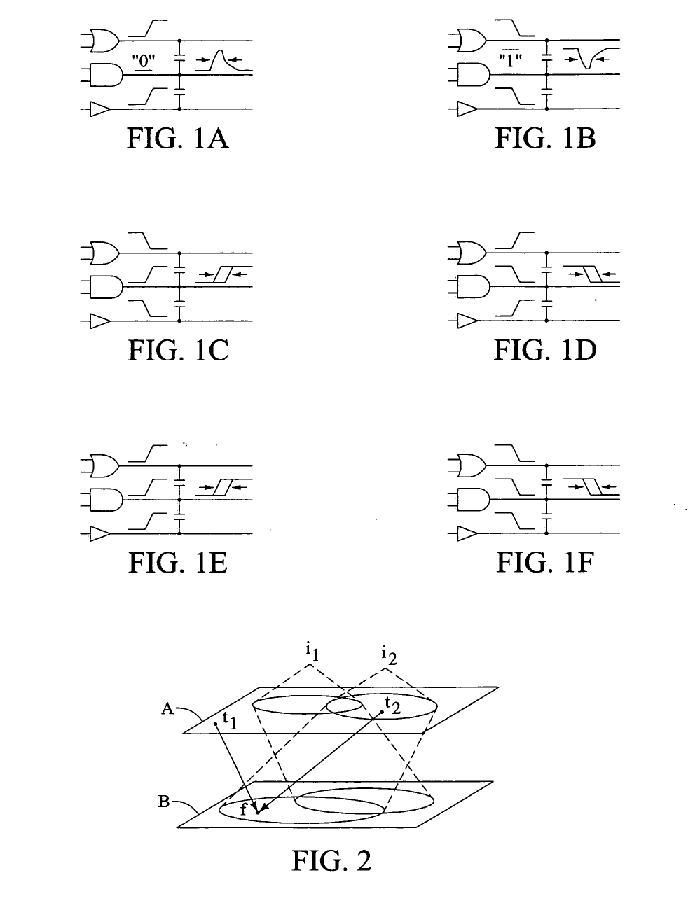

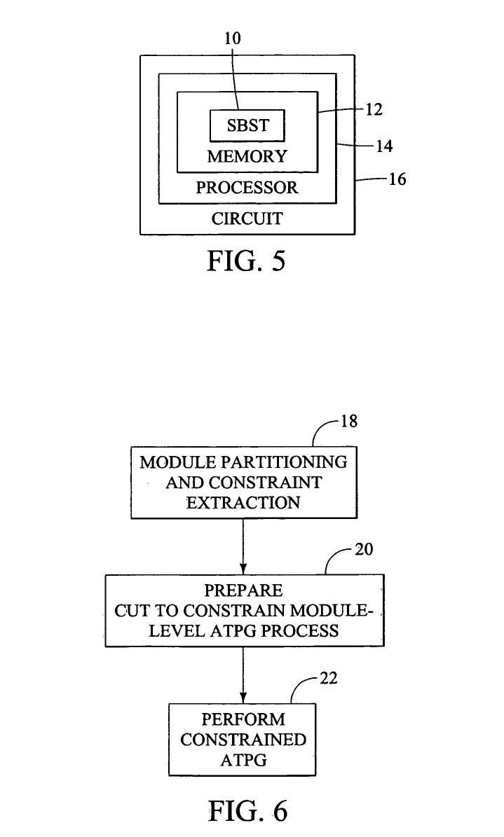

Turning now to FIG. 5, a software-based self-test (SBST) in accordance with one embodiment of the present invention is adapted to be implemented as a software program 10 installed in a memory 12 of a processor or controller 14 of a circuit under test (CUT) 16 which is being tested for AC faults. The implementation of the present invention is described with respect to crosstalk-induced logic and transition faults, which may include positive glitch, negative glitch, rising delay, falling delay, rising speedup and falling speedup, such as those shown in FIGS. 1A-1F. It should be understood, however, that the invention may also be applied to other AC fault models, such as path delay faults.

Turning now to FIG. 6, the present invention in accordance with one embodiment includes a first stage 18 for performing module partitioning and constraint extraction for all instructions, a second stage 20 for preparing the CUT 16 to constrain the module-level automatic test program generation (ATPG) process, containing the module under test (MUT) sandwiched between the controllability and observability virtual constraint circuits (VCCs), and a third stage 22 for performing constrained ATPG.

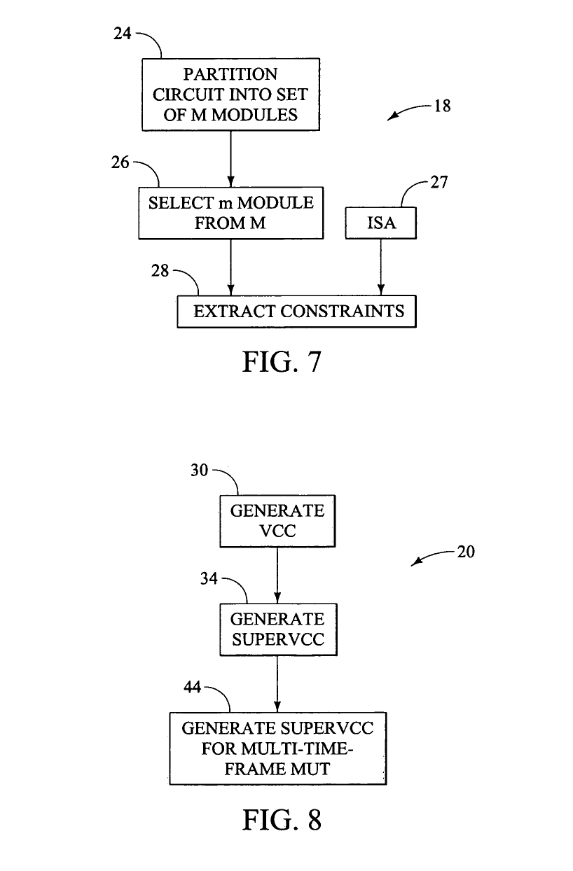

Referring to FIG. 7, the first stage 18 includes partitioning the circuit 16, into a set of modules M (not shown) based on its register-transfer lever (RTL) description (block 24), for example, in accordance with functional blocks. From this set of M modules one module m is selected to be tested (block 26). Then a simulation-based method is used to extract controllability and observability constraints for each MUT (block 28), including those imposed by the instruction set architecture (ISA) 27 and surrounding logic (not shown). The constraints are extracted by deriving input/output mapping functions using regression analysis techniques, as described in Chen et al. referenced above, for example.

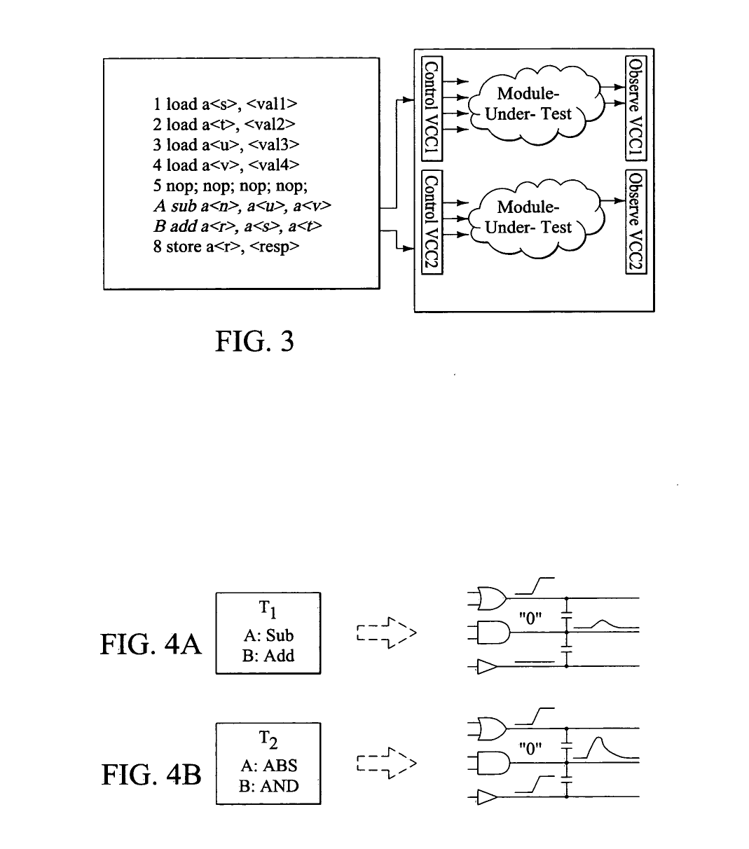

From the constraints extracted in stage 1 virtual constraint circuits (VCCs) are generated (block 30) in the second stage 20. In other words, the second stage 18 prepares a CUT 16 to constrain the module-level ATPG process, containing the MUT sandwiched between the controllability and observability VCCs. As described above, VCCs enforce instruction-imposed constraints on the MUT, providing constraint information in the form of logic circuits, as shown in FIG. 3. Controllability VCCs (CVCCs) and observability VCCs (OVCCs) are attached to the inputs and outputs of the MUT, respectively. If there are two instruction slots, for example, A and B as in FIG. 3, in the instruction sequence to be filled with appropriate instructions, since instructions from different timeframes have different VCCs, an ATPG tool (not shown) needs to handle a changing CUT across the timeframes. Although a time-varying CUT is required to represent constraints imposed by a sequence of instructions, the “right” instruction sequence for triggering the largest noise effect is not known a-priori. In Chen et al., the ATPG tool considers single-timeframe constraints by enumerating all CUTs with VCCs representing constraints imposed by individual instructions in the ISA. The same enumeration method is not feasible for multi-timeframe test generations, as the number of CUTs representing all possible instruction combinations grows exponentially as the length of the sequence grows.

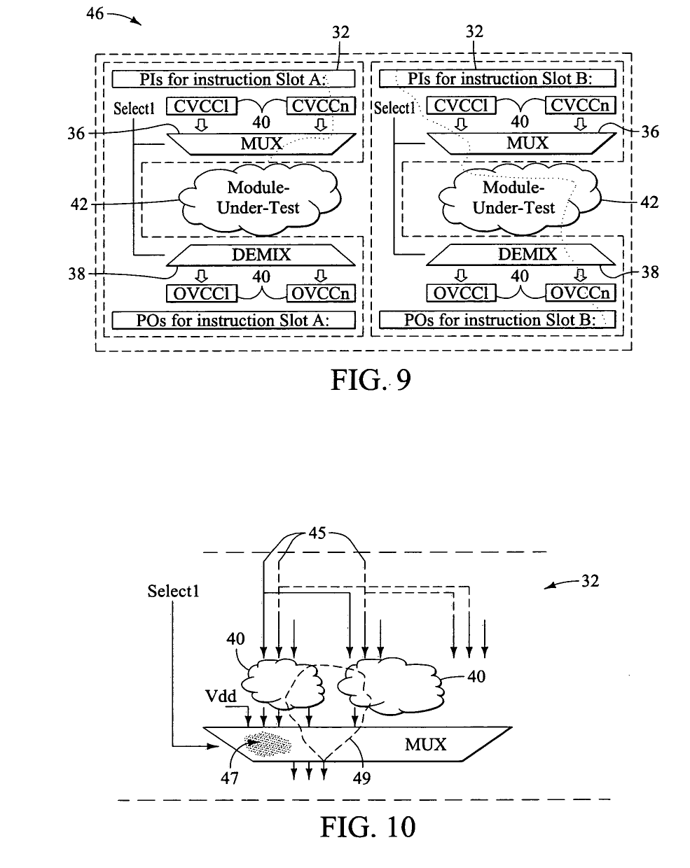

To overcome this difficulty, a Super Virtual Constraint Circuit (SuperVCC) 32 is generated (block 34), as shown in FIG. 9. Since ATPG tools make decisions based on structural information, we shift the responsibility of selecting the instruction sequence to the ATPG tool by making the choices of all instructions available to the ATPG tool in the form of the SuperVCC 32. The SuperVCC encapsulates all VCCs, representing constraints imposed by the entire ISA and surrounding logic in a single timeframe.

As shown in FIG. 9, a multiplexer (MUX) 36 and a demultiplexer (DEMUX) 38 are introduced to combine individual VCCs 40 for each MUT 42. A “select” signal is added to control the MUX 36 and DEMUX 38. Thus, the ATPG tool can later choose an instruction implicitly by assigning values to the “select” signal. After the generation of the SuperVCC 32, the MUT 42 is duplicated to enable test generation in multiple timeframes (block 44 in FIG. 8) (two timeframes shown in FIG. 9). The SuperVCC 32 is attached to the MUT 42 in each timeframe, representing constraints imposed by instructions from the corresponding timeframe.

A circuit consisting of the MUT and the SuperVCC spanning over multiple timeframes as shown in FIG. 9 forms the new CUT 46 seen by an ATPG tool to generate tests for crosstalk faults. Thus, instead of handling N CUTs (2 timeframes to consider for crosstalk faults), where N is the number of instructions in the ISA, the ATPG tool now only need to generate test for a single CUT. Note that the CUT 46 itself does not imply any particular instruction sequence. Rather, the selection of the instruction sequence triggering the desired noise effect is done by ATPG in stage 3 (block 22 shown in FIG. 6), without enumerating different CUTs.

The SuperVCC 32 is a virtual circuit that presents constraints to the ATPG tool. Simply connecting all VCCs together with MUX will make the SuperVCC 32 too complex and difficult for ATPG tool to handle. In one embodiment, common signals and logic redundancies are exploited to further reduce the complexity of the SuperVCC 32. As illustrated in FIG. 10, common settable fields 45 and observable fields of VCCs 40 are merged to reduce the total number of primary inputs (PIs) and primary outputs (POs). Many VCCs have signals either attach to logic “1” or logic “0”, hence the MUX and DEMUX can be tremendously trimmed (see trimmed area 47). For instructions belonging to one category (e.g. add, sub), frequently their VCCs share common logics 49 and signals. Thus, a logic synthesis tool is used to further simplify the SuperVCC 32.

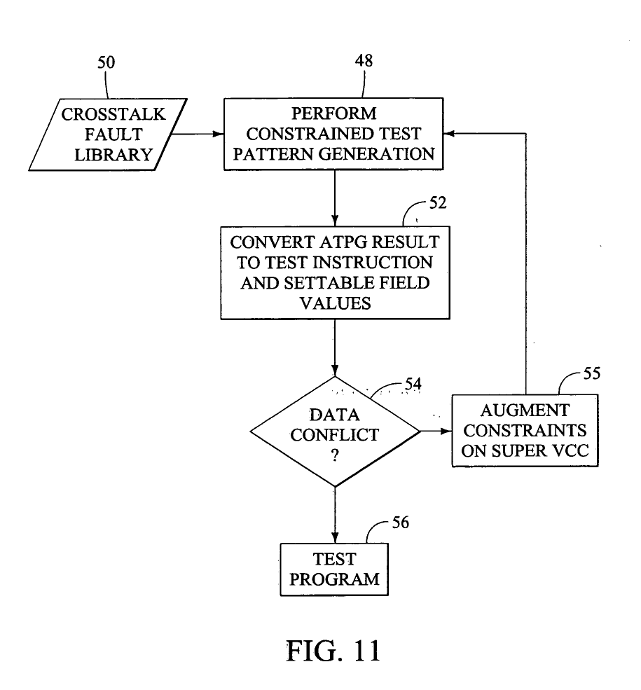

As shown in FIG. 11, stage 3 includes performing constrained test pattern generation. In one embodiment, an ATPG tool (not shown) is used to generate the test pattern. The test pattern generation outputs specified values for the “select” signals (shown in FIG. 9) and settable fields of the “selected” instructions (block 48). The constrained ATPG is performed with respect to certain parts of the circuit that are potential candidates for failures. These candidates are stored in a crosstalk fault library 50 which is compiled through various known means such as, for example, layout extraction, timing analysis, noise estimation and process variation analysis. The crosstalk fault library 50 is external to the processor 14 of the circuit 16 being tested. The test vectors resulting from constrained ATPG justify the logic values for the victim, trigger aggressors and sensitize a propagation path (shown as curved dotted lines in FIG. 9).

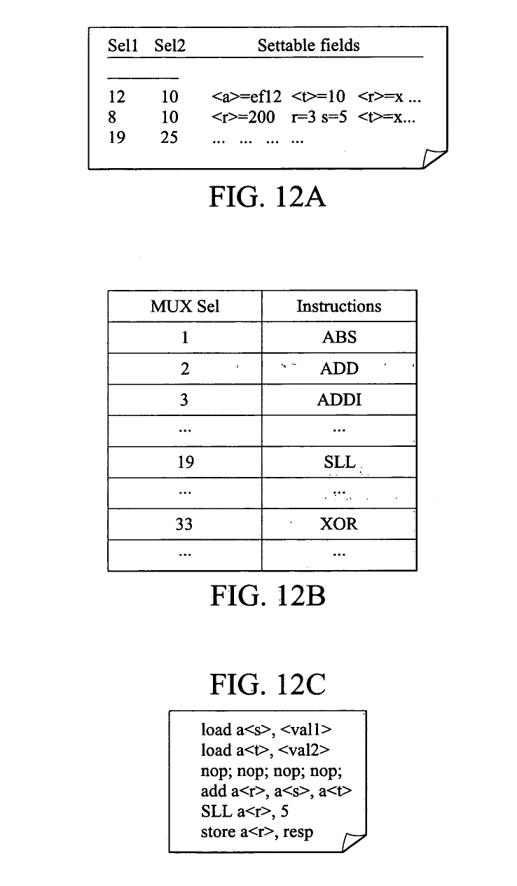

The ATPG results (a sample shown in FIG. 12A) are then converted to a test instruction sequences by mapping the values assigned to the “select” signals to corresponding instructions (a sample shown in FIG. 12B). Peripheral instructions are inserted to setup values for settable fields and save the test results (a sample shown in FIG. 12C) (block 52).

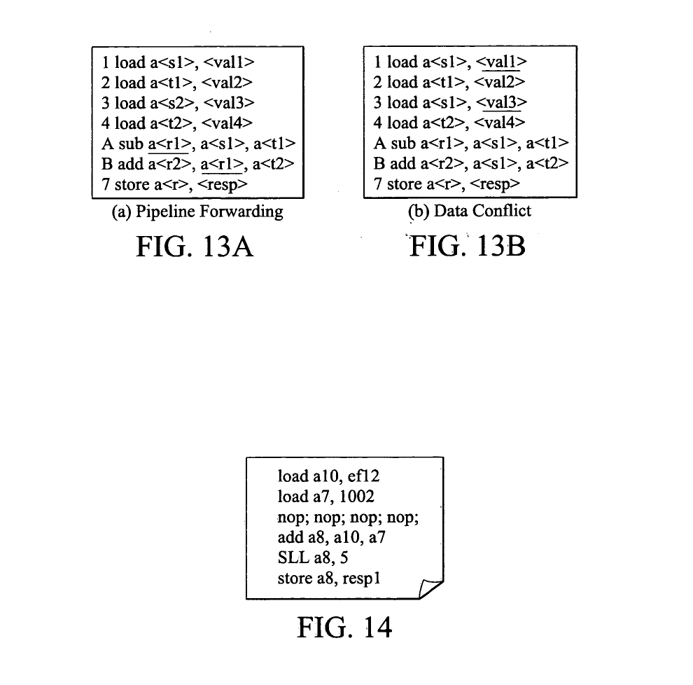

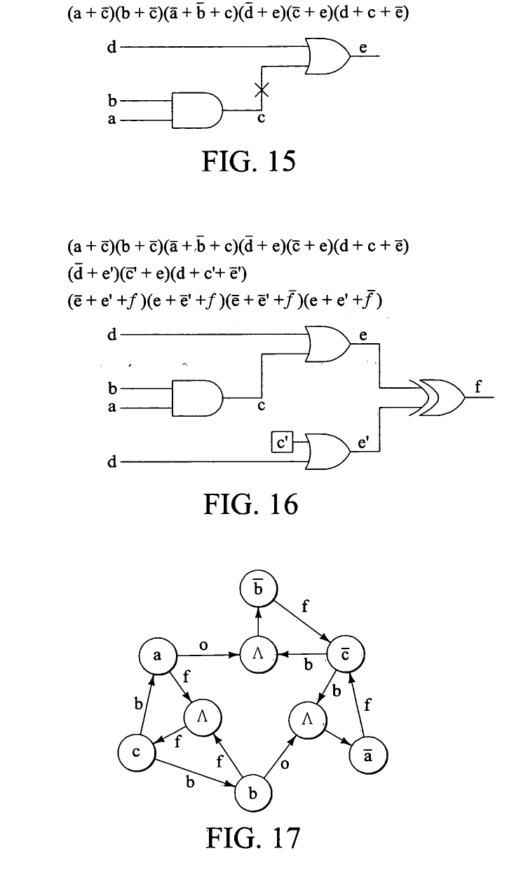

Once the ATPG results have been converted, a determination is made as to whether there is a data conflict (block 54). In other words, data-dependency related issues are considered. For example, FIGS. 13A and 13B show two typical situations. In 13A, test instruction B needs data from register r1 (underlined), which is being calculated by instruction A (underlined). However, in microprocessors with pipeline, for example, this data is not available unless pipeline forwarding is enabled. FIG. 13B, for example, shows for register s1, instruction A and instruction B require different values (<va11> and <va13>) and one of the tests cannot be delivered appropriately.

If there is no data conflict (block 54), a final test program (a sample shown in FIG. 14) is generated (block 56). If there is a conflict, we can utilize a conflict-aware value assignment process to intelligently take advantage of don't care signals in the ATPG results. For example, referring back to FIG. 13B, if we “don't care” about the value assigned to <va11>, in order to avoid conflicting values being assigned to <va11> and <va13>, we can assign the value of <va13> to <va11>. Data correlation consistency is ensured by careful assignments on don't care signals, leading to the access of non-conflict sources and destinations in the test instructions.

When data conflict cannot be resolved by the intelligent value assignments, the SuperVCC may be incrementally augmented (block 55) to include additional constraint for avoiding data conflict with the necessary constraints, forcing ATPG tool to avoid conflicts already occurred. In this manner, we reduce the complexity of the SuperVCC, which leads to an efficient test pattern generation process.

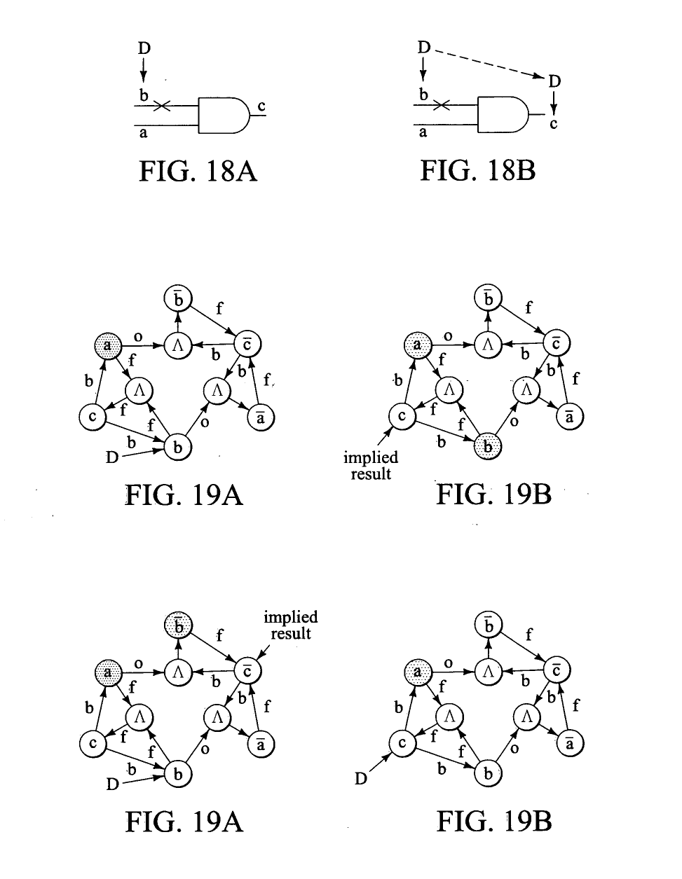

In one embodiment of the present invention, the ATPG method employed in the present SBST is a structural SAT-based ATPG method which combines both Boolean-satisfiability-based methods and structural-based method. It should be understood, however, that the present structural SAT-based ATPG method may also be used in other test methods, such as, for example, scan test or deterministic built-in self-test (BIST) methods. Turning now to FIGS. 18A and 18B, to eliminate the overhead of the duplication and large memory requirement of known ATPG methods employing an implication graph, we introduce a D frontier label in the implication graph. D frontier is used to denote the different behavior of the good circuit and the faulty circuit. By adding one extra label for each variable node to symbolize whether it is a D frontier, we can perform fast D frontier propagation on the implication graph without the duplication overhead.

When a fault is activated, the first D frontier will be introduced. For example, consider the circuit shown in FIG. 18A. Suppose fault b s-a-0 (stuck-at 0) is activated. Signal b should be 1 in the good circuit and 0 in the faulty circuit. Therefore, b will be assigned as the first D frontier. In order to further propagate D frontier though the AND gate to c (FIG. 18B), signal a has to be logic 1. Backtrace is performed from signal a to the primary inputs (PIs), and forward implication is used to try to justify the objective.

Suppose a=1 is successfully justified. To determine whether the D frontier can propagate though the AND gate, simulation is performed on the implication graph. For the good circuit, the b should be 1 and in the corresponding IG shown in FIG. 19B (FIG. 19A shows the state of the implication graph before propagation) node b is marked, and node c is implied. For the faulty circuit, b should be 0. Hence, node b is marked and node C is implied in FIG. 19C. The result nodes are node c and its complement c for the good circuit and the faulty circuit, respectively. Hence the D frontier can propagate though the AND gate and node c will be labeled as the new D frontier as shown in FIG. 19D.

By introducing the D frontier in the implication graph, we avoid the overhead of the duplication operation. The improved implication graph inherits advantages from both structural-based algorithms and SAT-based algorithms. Thus it enables faster logic conflict checking and logic implication operations.

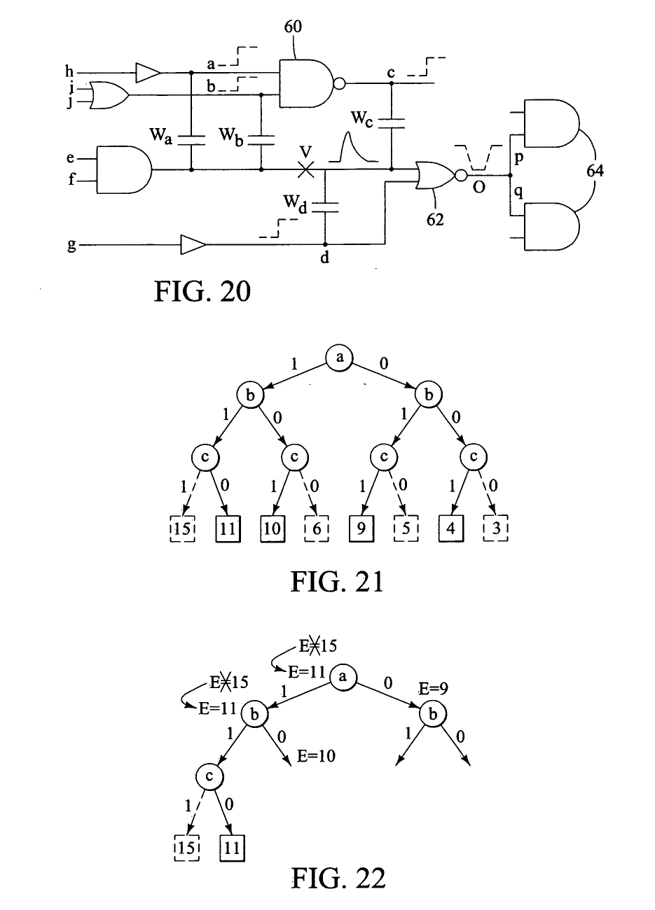

The goal of ATPG for AC faults such as crosstalk is to activate an error, propagate the error effect to POs and trigger as many aggressors as possible to attack the victim. However, the logic relations among the aggressors, the victim and potential propagation paths pose complicated constraints on the ATPG problem. FIG. 20 shows an example with multiple aggressors. The target error or victim is a positive glitch on wire v, and the potential aggressors are a, b, c, and
d. Dotted lines show the preferred transitions on the aggressors and the bold waveform shows the noise effect we intend to generate on the victim. Because of logic relation of the NAND gate 60, signals a, b and c cannot have rising transitions simultaneously. Also, in order for the noise effect to propagate though the NOR gate 62 and fit into the sampling windows at POs 64, d has to be logic 0 (using a single fault assumption).

Two vectors are needed to generate the desired transitions. According to their sequence relation to the transition, they can be denoted as before-switching vector and after-switching vector. We denote the logic value of aggressor i for before-switching as Aᵢ^{bs} and the logic value of aggressor i for after-switching as Aᵢ^{as}. Therefore, for a rising transition on aggressor i, we have, Aᵢ^{bs}=0 and Aᵢ^{as}=1.

Because of logic constraints, it is not always possible to trigger all the aggressors. If that happens, the ATPG algorithm should choose to activate a subset of most “important” aggressors to trigger a large noise effect. Using extracted layout information, and the crosstalk noise estimation tool described, for example, in “Noise-Aware Driver Modeling,” Proc. of International Symposium on Quality Electronic Design, pp. 177-182, 2003 by X. Bai, R. Chandra, S. Dey and P. V. Srinivas (Bai et al.) which is incorporated herein by reference, we assign a normalized weighting factor to each aggressor. This factor is used as a measure of how much the given aggressor can potentially contribute for the noise generation. For example, the contribution of aggressor i with weighting factor wᵢ to a positive glitch noise is wᵢ(Aᵢ^{as}−Aᵢ^{bs}). Therefore, the contribution is equal to wᵢ for a rising transition on the aggressor i, it is equal to −wᵢ for falling transition on i, and it is equal to 0 for the case of a quiet aggressor i.

Therefore, the ATPG problem can be formulated as an optimization problem. The objective is to activate the largest possible error effect subject to constraints including fault activation, fault propagation, and logic constraints of the circuit. Consider the positive glitch fault on victim v as an example. The problem can be formulated as:

$$Maximize {\sum }_{i ∈ aggressors}^{} {w}_{i} ( {A}_{i}^{as} - {A}_{i}^{bs} ) \qquad ( 1 )$$

Subject to:
v^{as}=0, v^{bs}=0; (fault activation)
Sensitized propagation path from v to PO

$$\begin{matrix}\begin{matrix}\begin{matrix}{A}_{i}^{bs} + {X}_{j}^{bs} + {X}_{k}^{bs} + {\overline{X}}_{i}^{bs} = 1 \\ {\overline{A}}_{i + 2}^{bs} + {\overline{X}}_{n}^{bs} + {X}_{k}^{bs} = 1\end{matrix} \} \begin{matrix}Logic constraints \\ ( before -\end{matrix} \\ ⋯\end{matrix} \\ \begin{matrix}{A}_{i}^{as} + {X}_{j}^{as} + {X}_{k}^{as} + {\overline{X}}_{i}^{as} = 1 \\ {\overline{A}}_{i + 2}^{as} + {\overline{X}}_{n}^{as} + {X}_{k}^{as} = 1\end{matrix} \} \begin{matrix}Logic contraints \\ ( after \text{-} switching )\end{matrix}\end{matrix}$$
Aᵢ, X, v ε {0,1}; A, X, v are signals of the CUT.

The patterns generated by ATPG should justify the appropriate logic values for the victim wire and propagate the error effect to primary output(s) PO(s). For a positive glitch on the victim v in the circuit shown in FIG. 20, v^{bs}=0 and v^{as}=0 are implied. When the after-switching vector is applied, the signal of wire v in the good circuit will be 0, and in the faulty circuit with a positive glitch, the signal of wire v should be 1 for some period and then fall back to 0. Similar to handling stuck-at faults, the D frontier can be used to denote the different behavior between the good circuit and the faulty circuit. The fault propagation can be achieved by propagating the D frontier for an equivalent stuck-at-I fault, from the faulty site to PO by the after-switching vector.

The ATPG problem is a 0-1 integer-programming problem and it is NP hard, which as those skilled in the art will recognize, is the complexity class of decision problems that are intrinsically harder than those that can be solved by a nondeterministic Turing machine in polynomial time. In other words, when a decision version of a combinatorial optimization problem is proved to belong to the class of NP-complete problems, which includes well-known problems such as satisfiability, traveling salesman, the bin packing problem, etc., then the optimization version is NP-hard.

In order to minimize the complexity, we use zero-delay model and assume that the circuit is hazard free. To further speedup the search process, the original optimization problem can be divided into two parts: before-switching and after-switching. For example, for a positive glitch, we want to trigger rising transitions on aggressors. The before-switching vector needs to justify 0 for the victim wire and to justify as many O's on the aggressors as possible. The after-switching vector need to justify a 0 for the victim, sensitize a path from the victim to PO(s), and to justify as many 1's on the aggressors as possible. Hence the original problem in (1) is divided into two parts with different constraints:
(a) Before-Switching:

$$Minimize {\sum }_{i ∈ aggressors}^{} {w}_{i} {A}_{i}^{bs} = Maximize {\sum }_{i ∈ aggressors}^{} {w}_{i} {\overline{A}}_{i}^{bs} \qquad ( 2 )$$

s.t.
Victim wire logic value (v^{b}=0 for positive glitch);
Logic constraints; and
(b) After-Switching:

$$Maximize {\sum }_{i ∈ aggressors}^{} {w}_{i} {A}_{i}^{as} \qquad ( 3 )$$
s.t.
Victim wire logic value (v^{a}=0 for positive glitch);
Propagation path from v to PO;
Logic constraints;
Note that the original objective function is transformed into two parts:
Maximize

$${\sum }_{i ∈ aggressors}^{} {w}_{i} ( {A}_{i}^{as} - {A}_{i}^{bs} )$$

equivalent to
(Maximize

$$( Maximize {\sum }_{i ∈ aggressors}^{} {w}_{i} {A}_{i}^{as} )$$

and (Maximize

$$( Maximize {\sum }_{i ∈ aggressors}^{} {w}_{i} {\overline{A}}_{i}^{bs} )$$

and each part is an optimization problem, with different constraints. In these equivalent optimization problems, if a rising transition occurs on aggressor Aᵢ, the total objective function value will be 2wᵢ; if a falling transition occurs, the total obj. function value will be 0; and if a stable 0 or stable 1, the obj. function value will be wᵢ. Hence it encourages rising transitions on as many “important” aggressors as possible. If we assume the two input vectors at PIs are not correlated, then we can solve these two parts separately.

In accordance with one embodiment of the invention, we introduce an algorithm to search for solutions for the above optimization problems using a single framework. If we could afford to evaluate all vectors satisfying the constraints in Equation (1), then we could compare them and select the one with the maximum objective function value. This is not feasible for large circuits.

In the present invention, an ATPG algorithm is divided into 2 phases. Given a crosstalk target fault consisting of a victim line and a set of potential aggressors, in the first phase we check if the set of aggressors is feasible. If not, we identify a subset of feasible aggressors. The outcome of the first phase is a set of objectives that need to be justified in the second phase. We use a modified PODEM algorithm to search for vectors justifying the multiple objectives. If the proposed set of aggressors fails in the second phase, the algorithm can iterate and select another set of relaxed objectives.

For both before-switching and after-switching vectors, there are several constraints that have to be satisfied by any pattern. These constraints result in mandatory assignments. First, the logic value of the victim should be justified. Second, if all the potential propagation paths share a common segment, this segment of the propagation path has to be sensitized, i.e., the corresponding side inputs of the segment need to be assigned and justified. For example, for the positive glitch on victim v in FIG. 20, v^{as}=0 and v^{bs}=0 are mandatory assignments. Since the NOR gate 62 is on the only possible propagation path, the signal value of the side input d needs to be considered. Even though a late rising transition on d may allow the noise to propagate though the NOR gate, because of our single fault assumption we do not consider this case as possible to allow the error to be sampled at POs. Hence, d^{as}=0 is a mandatory assignment and consequently, g^{as}=1 is implied. Initially, a D frontier is added for v. After assigning d^{as}=0, the D frontier propagates though the NOR gate 62, and variables p and q will be added to D frontier list. Next, since multiple potential propagation paths exist (p and q), no more mandatory assignments will be performed for the D frontier propagation.

The assignment of mandatory values and their implications are performed on the IG. Aggressors that have been assigned and/or implied mandatory values in this step will be removed from the set of aggressors under consideration for the next step. After the assignment of mandatory values, we need to further check the feasibility of the current set of aggressors. For easier understanding of our algorithm, we will use the search for after-switching vector for a positive glitch as an example. Because aggressor d was assigned a mandatory value 0 in the first step, we only need to consider signals a, b and c. Without loss of generality, let us assume that the weights of a, b and c are 6, 5 and 4, respectively. The implication graph is used to check for logic conflicts (described below).

Because each aggressor can be either logic 0 or 1, a binary decision diagram (BDD) tree can be constructed to fully explore all possible aggressor assignment combinations. FIG. 21 shows such a tree. The leaves (rectangles) of the BDD tree represent the total weights obtained by assigning aggressors according to the branches (circles) along the path from the root (top most circle) to leaves. Because of logic constraints, some branches of the tree are trimmed (e.g., a=0, b=0 and c=0). The trimmed branches and leaves are shown in dotted lines. The potentially feasible combinations can be sorted according to the weight of each leaf. Then, the combination with the highest value is chosen and the set of aggressor assignments act as objectives, which need to be justified in the next phase of the ATPG algorithm. If it turns out that no vector can justify these objectives, the process will be repeated with selecting the leaf with the second highest weight. This way, the search process keeps relaxing the objective function value until a solution is found or the weights of the remaining leaves are less than a given threshold value.

However, since the size of the BDD tree increases exponentially with the number of aggressors, it may not be affordable to fully explore the BDD tree. Building the whole tree and checking for logic conflicts for all possible combinations may be impossible for some circuits. In addition, each implication and unimplication operation could affect hundreds of variables on IG. Hence, each exploring step on the BDD tree may need expensive operations on IG. Therefore, in order to make the search more efficient, the necessary implication and unimplication operations are performed.

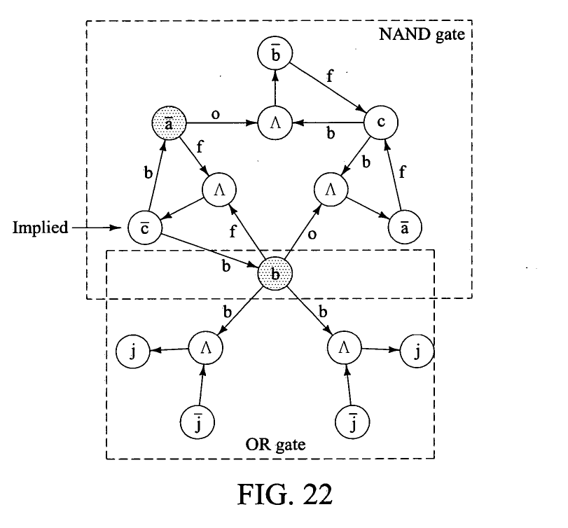

We develop a search algorithm to achieve this goal. Before exploring a node, we assume that the best combination of aggressors in the subtree of both branches is feasible. An expected value is calculated for the unexplored branches. The algorithm compares two branches of current node to decide which branch should be chosen. When conflict occurs or node in the downstream is implied, the expected values is updated. For example, in FIG. 22, we begin with node a. Since for branch a=0, the estimated value is 9, and for branch a=1 the estimated value is 15, we choose a=1. Implication on the IG will imply h and there is no conflict. Then algorithm will move on to node b, this time branch b=1 will be chosen. Again implication operation will be performed to check for conflicts.

During the implication operation, the objective list and D frontier list will be built and updated. Implication graph for the NAND and part of the OR gate of our example is shown in FIG. 23. Suppose during the implication operation for node b=1, the backward implication begins from variable b and it stops at the logic nodes before reaching variables i and j. Variable b will be added to the objective list (to be justified later). The forward implication begins from variable b. Since variable a has already been marked, c will be implied. The assigned nodes are marked in dark color, and the implication operations are shown in bold arrows in FIG. 23.

Because c is implied, branch c=1 will be trimmed on the BDD tree. The estimated values for all branches from the current node to the root will be updated. If the current node does not have the best estimated value anymore, unimplication will be performed, and the search process will move upward until it reaches a node containing a branch with the highest estimated value. To reduce the risk of jumping among different subtrees, the nodes should be sorted. In this example, the updated estimated value is 11 for nodes a and b (FIG. 22) meaning that the current branch still has the best estimated solution. The search process will continue till it reaches a leaf (a=1, b=1 and c=0).

Both structural algorithms and Boolean Satisfiability algorithms are employed to efficiently justify objectives and propagate AC fault to observable nodes (such as POs). In one embodiment, we use similar strategy as the PODEM (path-oriented decision making) algorithm described in “An implicit enumeration algorithm to generate tests for combinational logic circuits,” IEEE Trans. Comput., Vol. C-30, pp. 215-222, March 1981, by P. Goel, making decisions only on PIs to minimize the search space. The PODEM algorithm is modified such that Boolean Satisfiability algorithms can be used in each step of justification and implication on an IG.

First, the objectives are extracted from the objective list. BACKTRACE process will search and return an unassigned PI variable. Backtrace determines which primary input and value to set to achieve objective. Then forward implication is performed. Objectives will also be generated by D frontiers to guide the modified PODEM algorithm to sensitize propagation path(s). After each forward implication, D simulation is performed to propagate D frontiers and check whether D frontier reached PO(s). Below is one embodiment of the pseudo code for the modified PODEM, i.e., PODEM built on implication graph such that the switching between structural based ATPG algorithms and Boolean Satsifiability algorithms can be performed substantially seamlessly.

Modifed_PODEM( )

Begin

If(D at PO and objective list is

empty)

return SUCCESS

If(D frontier list is empty and not

reach PO)

return FAILED

(k,vₖ)=OBJECTIVE( )

(j,vⱼ)=BACKTRACE(k,vₖ) /* j is a PI

*/

if(IMPLY(j,vⱼ))

{

D_Simulation( )

if(Modified_PODEM( )= =SUCCESS)

return SUCCESS

}

UNIMPLY(j,vⱼ)

/*reverse PI assignment*/

if(IMPLY(j,\overline{vⱼ}))

{

D_Simulation( )

If

(Modified_PODEM( )= =SUCCESS)

return SUCCESS

}

UNIMPLY(j,\overline{vⱼ})
Return FAILED

END

Procedures used in the modified PODEM include BACKTRACE for backtracing from a given variable to primary inputs; and IMPLY for forward implications from PIs and checking for logic conflicts. The D frontier propagation is performed by D simulation as explained above.

The search for potential feasible objectives for the before-switching vector is similar to the after-switching vector, but the algorithm does not need to consider D frontier propagation and the preferred logic value is 0 for aggressors (since we are considering a positive glitch on the victim). Hence, the weights are assigned to \overline{a},\overline{b} and \overline{c}. The same framework for solving the ATPG problem as an optimization problem is used again. In one embodiment, the present ATPG algorithm is implemented in C++.

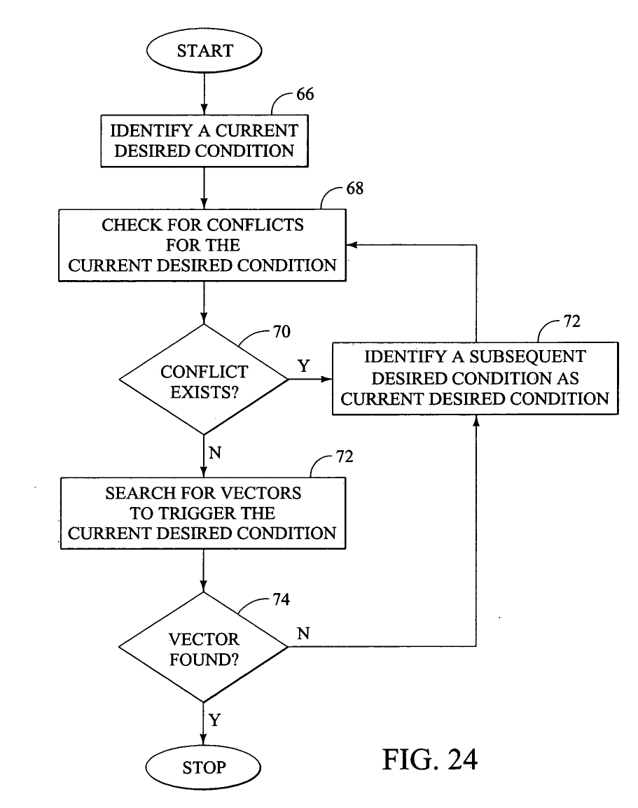

Turning now to FIG. 24, the operation of the automatic test pattern generation (ATPG) method in accordance with one embodiment of the present invention is described. First a desired condition for triggering the AC fault is identified (block 66). The ATPG algorithm then checks for potential conflicts for the current desired condition (block 68). If conflict exists (block 70), a subsequent desired condition will be identified and set as the current desired condition (block 72). The process will iterate until the current desired condition been found is potentially feasible (conflict free). Then Boolean Satisfiability algorithms and structural algorithms will be used to search for vectors to trigger the current desired condition (block 74). If no vector can be found to trigger the current desired condition (block 76), the process will iterate back to search for another current desired condition (block 72).

In one embodiment, the conflicts are results of logic relation among the victim, the aggressors, as well as mandatory assignments on the propagation path(s). If a logic conflict(s) exists, a subset of the initial set of aggressors is searched based on weights assigned to the aggressors. As a result, a set of potentially feasible aggressors are proposed as the objectives for justification. Once the feasible aggressors have been identified, a modified PODEM algorithm is used to search for vectors that can justify the required logic value for the victim, activate the aggressors and sensitize a propagation path.

While specific embodiments of the present invention have been shown and described, it should be understood that other modifications, substitutions and alternatives are apparent to one of ordinary skill in the art. Such modifications, substitutions and alternatives can be made without departing from the spirit and scope of the invention, which should be determined from the appended claims.

Various features of the invention are set forth in the appended claims.

1. A method for generating a test program for a software-based self-test in an integrated circuit, said method comprising:
extracting a plurality of constraints for corresponding instructions for the integrated circuit;
modeling said plurality of constraints for a plurality of timeframes;
performing constrained test pattern generation on the integrated circuit using said plurality of models; and
converting a result from said test pattern generation to at least one instruction executable by the integrated circuit.

2. The method as defined in claim 1, wherein said test program tests target AC faults in the integrated circuit.

3. The method as defined in claim 1, wherein said step of extracting a plurality of constraints comprises partitioning said circuit into a plurality of modules and extracting a plurality of constraints for corresponding instructions for each of said modules.

4. The method as defined in claim 1 wherein said modeling of said plurality of constraints comprises generating a plurality of virtual constraints circuits for said plurality of timeframes.

5. The method as defined in claim 4, wherein said virtual constraint circuits comprise a plurality of controllability constraints and a plurality of observability constraints.

6. The method as defined in claim 1, wherein said constraints are extracted by deriving input/output mapping functions using regression analysis techniques.

7. The method as defined in claim 1, wherein said performing constrained test pattern generation comprises selecting at least one of said modeled constraints for said plurality of timeframes.

8. The method as defined in claim 7, wherein said modeled constraints are selected using a multiplexer and/or a demuliplexer.

9. The method as defined in claim 1, wherein said result from said test pattern generation comprises a test pattern from at least one timeframe of said plurality of timeframes.

10. The method as defined in claim 9, wherein said result from said test pattern generation comprises a sequence of test patterns from said plurality of timeframes.

11. The method as defined in claim 1, wherein said constrained test pattern generation comprises using an automatic test pattern generation tool.

12. The method as defined in claim 1 further comprising, determining whether said result from said test pattern generation conflicts with an instruction set architecture of the integrated circuit.

13. The method as defined in claim 12 further comprising amending at least one of said constraints to avoid said conflict, if said result conflicts with said instruction set architecture.

14. The method as defined in claim 12 further comprising deterministically assigning values to don't care signals resulting from said test pattern generation to avoid said conflict, if said result conflicts with said instruction set architecture.

15. A test program for a software-based self-test for AC faults in an integrated circuit, said software-based self-test being stored in at least one of the integrated circuit being tested and tangible computer readable media, said test program comprising:
extracting a plurality of constraints for corresponding instructions for the integrated circuit;
modeling said plurality of constraints for a plurality of timeframes;
performing constrained test pattern generation on the integrated circuit using said plurality of models; and
converting a result from said test pattern generation to at least one instruction executable by the integrated circuit.

16. The test program as defined in claim 15 wherein said modeling of said plurality of constraints comprises generating a plurality of virtual constraints circuits for said plurality of timeframes.

17. An automatic test pattern generation method for a least one AC fault in an integrated circuit, said method comprising:
identifying a current desired condition for triggering the AC fault;
determining whether said current desired condition for triggering the AC fault is feasible;
identifying a subsequent desired condition for triggering the AC fault if said current desired condition is not feasible;
determining whether said subsequent desired condition for triggering the AC fault is feasible; and
searching for test vectors for realizing one of said current desired condition and said subsequent desired condition which is determined to be feasible for triggering the AC fault.

18. The method as defined in claim 17 wherein said determining whether said current desired condition for triggering the AC fault is feasible comprises using structural algorithms and Boolean satisfiability algorithms.

19. The method as defined in claim 17 wherein said searching for test vectors comprises using structural algorithms and Boolean satisfiability algorithm.

20. The method as defined in claim 17, wherein said identifying said subsequent desired conditions comprises evaluating at least one cost function for triggering AC faults.

21. The method as defined in claim 17, wherein, said identifying said current desired condition comprises identifying a set of current aggressors capable of triggering a victim from a plurality of potential aggressors; and said identifying said subsequent desired condition comprises identifying a set of subsequent aggressors capable of triggering the victim from said plurality of potential aggressors

22. The method as defined in claim 21, wherein said identifying said subsequent desired conditions comprises evaluating at least one cost function with respect to said plurality of potential aggressors for triggering AC faults.

23. The method as defined in claim 21, wherein said determining whether said current desired condition for triggering the AC fault is feasible comprises determining whether said set of current aggressors are feasible for triggering the victim, and said determining whether said subsequent desired condition for triggering the AC fault is feasible comprises determining whether said set of subsequent aggressors are feasible for triggering the victim.

24. The method as defined in claim 23, wherein said searching for test vectors comprises using structural algorithms and Boolean satisfiability algorithms in which decisions are made based on at least structural and logical information of the circuit.

25. The method as defined in claim 24 wherein said structural algorithm comprises a PODEM algorithm.

26. The method as defined in claim 24, wherein said Boolean satifiability algorithm and said structural algorithm perform checking conflicts, backtracing from a plurality of signals implicated by aggressors and mandatory propagation paths to primary inputs of the circuit, and forward implications from said primary inputs.

27. The method as defined in claim 23, wherein said determination of whether said set of current or subsequent aggressors are feasible comprises checking for logic conflicts among at least the victim, the aggressors and the propagation paths of the circuit.

28. The method as defined in claim 27, wherein said checking for logic conflicts is performed using an implication graph with the plurality of potential aggressors and a plurality of potential propagation paths.

29. The method as defined in claim 28, wherein said checking for logic conflicts further comprises introducing mandatory values to said implication graph.

30. The method as defined in claim 21, wherein said identifying said set of subsequent aggressors comprises selecting from said plurality of potential aggressors based on weights assigned to said selected aggressors and evaluating a cost function.

31. The method as defined in claim 30, wherein said weights are assigned to said plurality of potential aggressors based on noise analysis.

32. The method as defined in claim 30, wherein said cost function is evaluated based on a formula,
$$Maximize {\sum }_{i ∈ aggressors}^{} {w}_{i} ( {A}_{i}^{as} - {A}_{i}^{bs} ) \qquad ( 1 )$$
Subject to:
v^{as}=0, v^{bs}=0; (fault activation)
Sensitized propagation path from v to PO
$$\begin{matrix}\begin{matrix}\begin{matrix}{A}_{i}^{bs} + {X}_{j}^{bs} + {X}_{k}^{bs} + {\overline{X}}_{i}^{bs} = 1 \\ {\overline{A}}_{i + 2}^{bs} + {\overline{X}}_{n}^{bs} + {X}_{k}^{bs} = 1\end{matrix} \} \begin{matrix}Logic constraints \\ ( before -\end{matrix} \\ ⋯\end{matrix} \\ \begin{matrix}{A}_{i}^{as} + {X}_{j}^{as} + {X}_{k}^{as} + {\overline{X}}_{i}^{as} = 1 \\ {\overline{A}}_{i + 2}^{as} + {\overline{X}}_{n}^{as} + {X}_{k}^{as} = 1\end{matrix} \} \begin{matrix}Logic contraints \\ ( after \text{-} switching )\end{matrix}\end{matrix}$$
where Aᵢ, X, v ε {0,1}; A, X, v are signals of the CUT, and Aᵢ^{bs} denote the logic value of aggressor i for before-switching, Aᵢ^{as} denote the logic value of aggressor i for after-switching, and wᵢ(Aᵢ^{as}−Aᵢ^{bs}) is the contribution of aggressor i with weighting factor wᵢ to a positive glitch noise.

33. The method as defined in claim 32, wherein said weighting factor wᵢ is assigned based on noise analysis and/or simulation results.

34. The method as defined in claim 32, wherein said formula (1) comprises,
$$Minimize {\sum }_{i ∈ aggressors}^{} {w}_{i} {A}_{i}^{bs} = Maximize {\sum }_{i ∈ aggressors}^{} {w}_{i} {\overline{A}}_{i}^{bs}$$
s.t.
Victim wire logic value (v^{b}=0 for positive glitch);
Logic constraints; and
$$Maximize {\sum }_{i ∈ aggressors}^{} {w}_{i} {A}_{i}^{as}$$
s.t.
Victim wire logic value (v^{a}=0 for positive glitch);
Propagation path from v to PO;
Logic constraints.

35. The method as defined in claim 30, wherein said selecting aggressors based on weights assigned to said selected aggressors comprises using an algorithm for selectively choosing aggressor nodes in a binary decision diagram (BDD) tree based on an expected weight value for both branches of a node, wherein said algorithm updates said expected weight value when a logic conflict occurs or a node downstream is implied.

36. The method as defined in claim 17 wherein said automatic test pattern generation method is adapted to be incorporated in a software-based self-test for the integrated circuit.
